(19) United States
(12) Patent Application Publication
(10) Pub. No.: US 2014/0049925 A1
(43) Pub. Date: Feb. 20, 2014

(54) CIRCUIT BOARD HOUSING ASSEMBLY HAVING A SECURING CLIP

(71) Applicants: Robert F. Martens, JR., Bay City, MI (US); Robert R. Voltenburg, JR., Davison, MI (US)

(72) Inventors: Robert F. Martens, JR., Bay City, MI (US); Robert R. Voltenburg, JR., Davison, MI (US)

(73) Assignee: STEERING SOLUTIONS IP HOLDING CORPORATION, Saginaw, MI (US)

(21) Appl. No.: 13/589,512

(22) Filed: Aug. 20, 2012

(51) Int. Cl. H05K 7/14; H05K 13/00

(52) U.S. Cl. 361/759; 29/592.1

(57) ABSTRACT

A housing assembly is provided, and includes a circuit board, a housing, and a clip. The circuit board has a main body and a ground plane. The main body defines an opening therethrough in the circuit board. The housing receives the circuit board. The clip for secures the circuit board to the housing. The clip includes a projecting tab and a flange. The projecting tab is received by the opening in the circuit board and the flange contacts the ground plane.

### BACKGROUND OF THE INVENTION

The present invention relates to a housing assembly, and more particularly to a housing assembly having a clip for securing a circuit board to a housing.

A printed circuit board (PCB) or control card assembly (CCA) is typically secured within a housing by inserting a fastener, such as a screw, through a screw opening located within the PCB. The screw may then be inserted into a threaded opening in the housing. In one approach, the screw may be used to provide grounding to the PCB. The PCB may also need to comply with an electromagnetic compliance (EMC) standard which defines levels of allowable electromagnetic interference (EMI) noise. The screw may also be used to attenuate EMI noise as well.

An area or zone surrounding the screw opening in the PCB does not generally include any electrical componentry. This is because the zone surrounding the screw opening is used to accommodate a screw driver or screw gun. Also, there are relatively high stresses generated in the PCB in the zone surrounding the screw created by the screw fastening process that may affect electrical components. However, because electrical components are not allowed in the areas surrounding the screw opening, this may increase the overall size of the PCB. Thus, accommodating one or more screws on a PCB may be challenging, especially if the housing and PCB have relatively tight packaging restraints.

### SUMMARY OF THE INVENTION

According to one aspect of the invention, a housing assembly is provided that includes a circuit board, a housing, and a clip. The circuit board has a main body and a ground plane. The main body defines an opening therethrough in the circuit board. The housing receives the circuit board. The clip for secures the circuit board to the housing. The clip includes a projecting tab and a flange. The projecting tab is received by the opening in the circuit board and the flange contacts the ground plane.

According to another aspect of the invention, an electric power steering (EPS) assembly is provided including a circuit board, a housing, and a clip. The circuit board has a main body and a ground plane. The main body defines an opening therethrough in the circuit board. The housing receives the circuit board. The clip secures the circuit board to the housing. The clip includes a projecting tab, a flange, and a projection. The projecting tab is received by the opening in the circuit board. The flange contacts the ground plane. The projection makes contact with a portion of the housing.

According to yet another aspect of the invention, a method of securing a circuit board to a housing by a clip is provided. The method includes placing a projecting tab of the clip within an opening of the circuit board. The method includes seating a flange of the clip against a ground plane of the circuit board. The method includes sliding a projection of the clip over an edge of the housing to secure the clip to the circuit board and the housing.

These and other advantages and features will become more apparent from the following description taken in conjunction with the drawings.

### BRIEF DESCRIPTION OF THE DRAWINGS

The subject matter which is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 is an illustration of a housing assembly including a circuit board and a clip in accordance with an exemplary embodiment of the invention;

FIG. 2 is a cross-sectional view of the housing assembly shown in FIG. 1, in accordance with another exemplary embodiment of the invention;

FIG. 3A illustrates a side view of the clip as shown in FIGS. 1-2, in accordance with another exemplary embodiment of the invention;

FIG. 3B illustrates a front view of the clip as shown in FIGS. 1-2, in accordance with yet another exemplary embodiment of the invention;

FIG. 3C illustrates a plan view of the clip as shown in FIGS. 1-2, in accordance with an exemplary embodiment of the invention;

FIG. 4 illustrates a tool for securing the clip to the housing assembly, in accordance with another exemplary embodiment of the invention; and

FIG. 5 is a process flow diagram illustrating an approach for securing the clip to the housing assembly.

### DETAILED DESCRIPTION

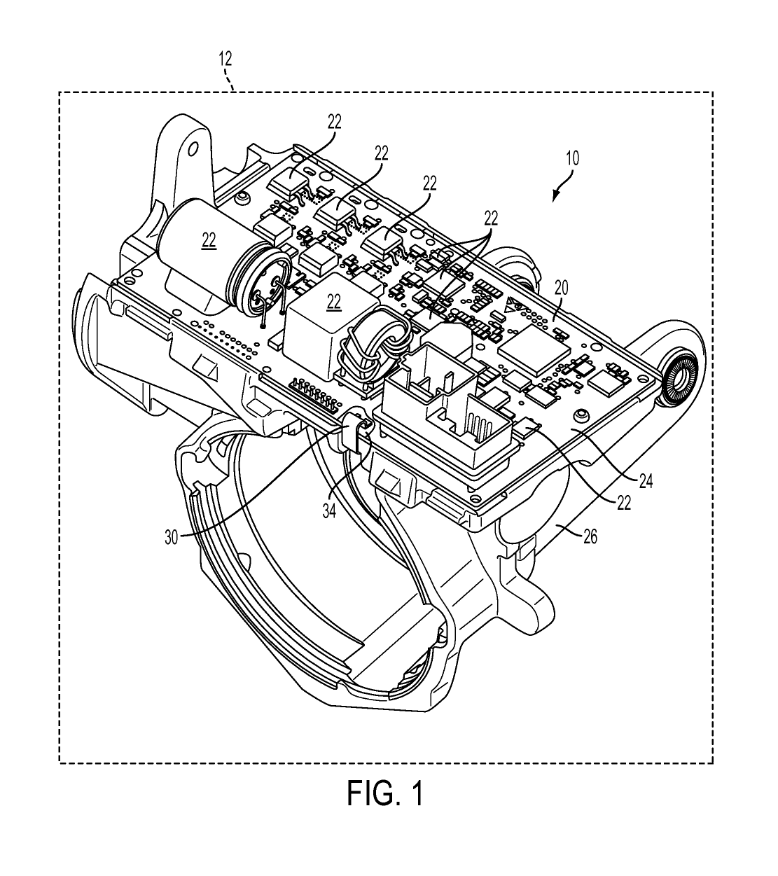

Referring now to FIG. 1, where the invention will be described with reference to specific embodiments without limiting same, an exemplary embodiment of a housing assembly 10 for use in an electric power steering (EPS) assembly 12 (shown schematically) including a circuit board 20 is illustrated. The circuit board 20 is generally any type of board used to mechanically support and electrically connect various electronic components 22 using conductive pathways, tracks or signal traces etched from conductive material laminated onto a main body that is a non-conductive substrate 24. In various embodiments the circuit board 20 may be, for example, a printed circuit board (PCB) or a circuit card assembly (CCA). A housing 26 is provided for receiving the circuit board 20. At least one clip 30 is provided to secure the circuit board 20 to the housing 26. In the exemplary embodiment the housing assembly 10 is part of the EPS assembly 12, however, it is to be understood that the housing assembly 10 may be used in various other applications as well.

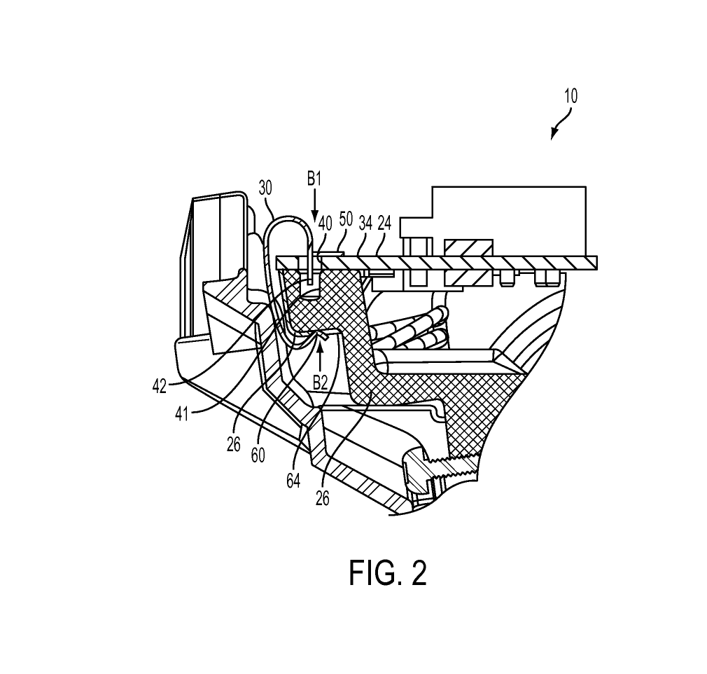

A ground plane 34 may be disposed along a surface 36 of the non-conductive substrate 24. The ground plane 34 is generally a layer of electrically conductive material (e.g., copper foil). Turning now to FIG. 2, a cross-sectional view of a portion of the housing assembly 10 is illustrated. Referring to both FIGS. 1-2, the non-conductive substrate 24 of the circuit board 20 defines an opening 40 (shown in FIG. 2). The opening 40 is configured for receiving a portion of the clip 30. In the embodiment as shown, the housing 26 also defines an opening 41 for also receiving a portion of the clip 30. Specifically, the openings 40 and 41 receive a projecting tab 42 of the clip 30. In one approach, the opening 40 of the circuit board 20 may be located within or adjacent to the non-conductive substrate 24 such that when the opening 40 receives the projecting tab 42 of the clip 30, a ledge or flange 50 of the clip 30 makes contact with the ground plane 34.

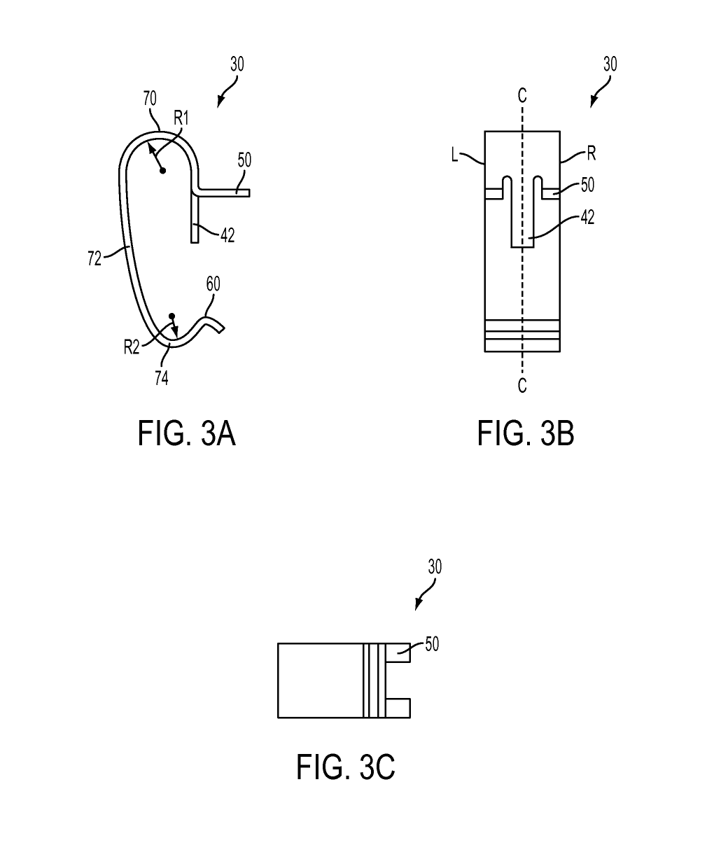

FIGS. 3A-3C illustrate various views of the clip 30, where FIG. 3A is a side view, FIG. 3B is a front view, and FIG. 3C is a plan view of the clip 30. Referring now to FIGS. 2 and 3A-3C, the flange 50 makes contact with the ground plane 34 (shown in FIGS. 1-2). A portion of the flange 50 defines the projecting tab 42. That is, as seen in FIG. 3A, a portion of the flange 50 is bent, oriented or aligned in a direction generally perpendicular to the flange 50 to create the projecting tab 42. It should be noted that while FIG. 3A illustrates the projecting tab 42 oriented generally perpendicular to the flange 50, it is understood that the projecting tab 42 may be oriented relative to the flange 50 in other alignments as well, such as less than 90° or more than 90°. It should also be understood that while FIG. 3B illustrates the projecting tab 42 positioned along a midsection C-C of the clip 30, the projecting tab 42 may also be offset from the midsection C-C as well, relative to either a left portion L or to a right portion R of the clip 30.

Referring now to FIGS. 2 and 3A-3C, the clip 30 also includes a raised portion or projection 60 that makes contact with a surface 64 of the housing 26. In an exemplary embodiment (not shown), the projection 60 may include serrations, a knurled surface, or distinct teeth to aid in contact retention with the surface 64. In one embodiment, the housing 26 may be constructed from an electrically conductive material that grounds the clip 30 and the circuit board 20 such as, for example, aluminum.

The clip 30 is generally constructed from an electrically conductive, relatively flexible material such as, for example, spring steel (e.g., 1050 spring steel). Specifically, the clip 30 is constructed from a relatively flexible material that allows for the clip 30 to exert a biasing force upon the circuit board 20 and the housing 26. The flange 50 of the clip 30 exerts a first biasing force B1 upon the ground plane 34 of the circuit board 20, and the projection 60 exerts a second biasing force B2 upon the housing 26. In the embodiment as shown in FIG. 2, the first biasing force B1 and the second biasing force B2 generally oppose one another. The first biasing force B1 and the second biasing force B2 exerted by the clip 30 cooperate together to clamp or secure the circuit board 20 to the housing 26.

Referring now to FIG. 3A, the clip 30 includes a first generally arcuate section 70, a connecting section 72, and a second generally arcuate section 74. In the embodiment as shown in FIG. 3A, the first generally arcuate section 70 includes a profile that starts at the flange 50 and arcs about 180° to connect with the connecting section 72. The second generally arcuate section 74 includes a profile that starts at the projection 60 and also arcs about 180° to connect with the connecting section 72. The first generally arcuate section 70 includes a first radius R1 and the second generally arcuate section 74 includes a second generally arcuate section 74. In the exemplary embodiment as shown in FIG. 3A, the first radius is greater than the second radius R2. However, it is to be understood that in alternative approaches the first radius R1 may be about equal to the second radius R2, or the first radius R1 may be less than the second radius R2 as well depending on the application and specific geometry of the housing 26 and the circuit board 20.

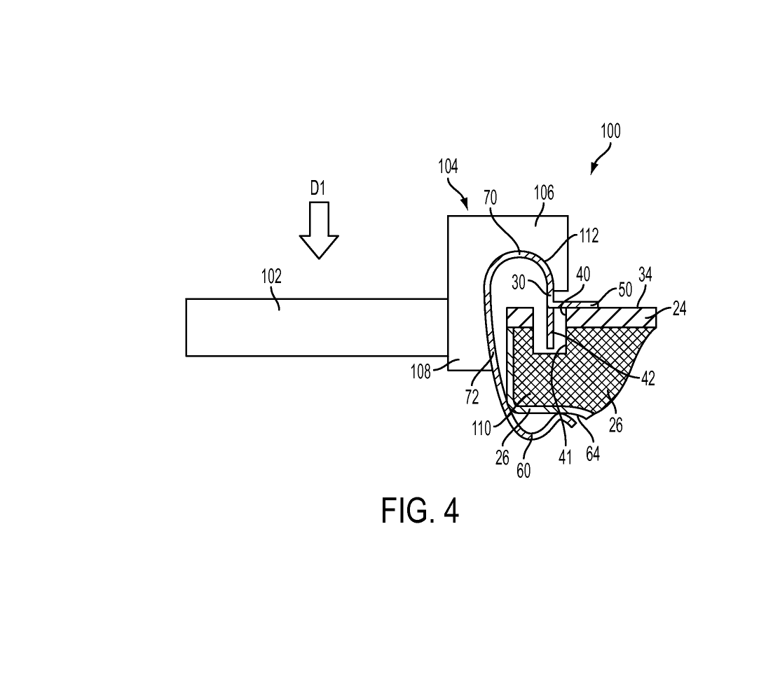

Turning now to FIG. 4, an assembly illustration is shown, where a tool 100 is provided to secure the clip 30 to the housing 26. In the embodiment as shown in FIG. 4, the tool 100 includes a handle portion 102 and a securing portion 104. During assembly of the clip 30, an operator may grasp the tool 100 using the handle 102. The securing portion 104 may include a profile that generally conforms to an outer profile 112 of the clip 30. A first portion 106 of the securing portion 104 is configured to make contact with the first generally arcuate section 70 of the clip 30, and a second portion 108 of the securing portion 104 is configured to make contact with the connecting section 72 of the clip 30. The first portion 106 of the tool 100 may extend to the flange 50 of the clip 30. With reference to both FIGS. 2 and 4, the clip 30 is assembled to the housing assembly 10 by first placing the projecting tab 42 of the clip 30 within the opening 40 of the non-conductive substrate 24 and the opening 41 of the housing 26 by an operator. The flange 50 is seated against the ground plane 34 of the circuit board 20.

The tool 100 is then used to slide the projection 60 of the clip 30 over an edge 110 of the housing 26, thereby securing the clip 30 to the circuit board 20 and the housing 26. Specifically, an operator directs the tool 100 and exerts a force in a direction D1 that is generally orthogonal to the housing 26. In the embodiment as shown in in FIG. 4, the direction D1 is generally orthogonal to the surface 64 of the housing 26. The second portion 108 of the tool 100 then urges the projection 60 of the clip 30 over the edge 110 of the housing 26. The projection 60 of the clip 30 then snaps or clips into position along the surface 64 of the housing 26. Although FIG. 4 illustrates the direction D1 generally orthogonal to the housing 26, the tool 100 may be oriented in other directions as well. However, orienting the tool 100 generally orthogonal to the housing 26 may enhance operator ergonomics.

Referring generally to FIGS. 1-4, the clip 30 is used to secure the circuit board 20 to the housing 26. The clip 30 may also be used to ground the circuit board 20 (e.g., through the grounding plane 34 of the circuit board 20 and the conductive material the housing 26). The clip 30 may also be used to attenuate electromagnetic interference (EMI) noise as well. Some types of circuit boards currently available utilize a screw for securement of the circuit board, grounding, and to attenuate EMI noise. However, unlike a screw, the clip 30 does not require a zone without electrical componentry surrounding the opening 40. This results in the circuit board 20 having a reduced size. Moreover, instead of a relatively expensive screw gun that is used to fasten the screw to the circuit board, the tool 100 (shown in FIG. 4) may be used to fasten the clip 30 to the circuit board 30. The tool 100 may be significantly less expensive than a screw gun, resulting in significant cost savings.

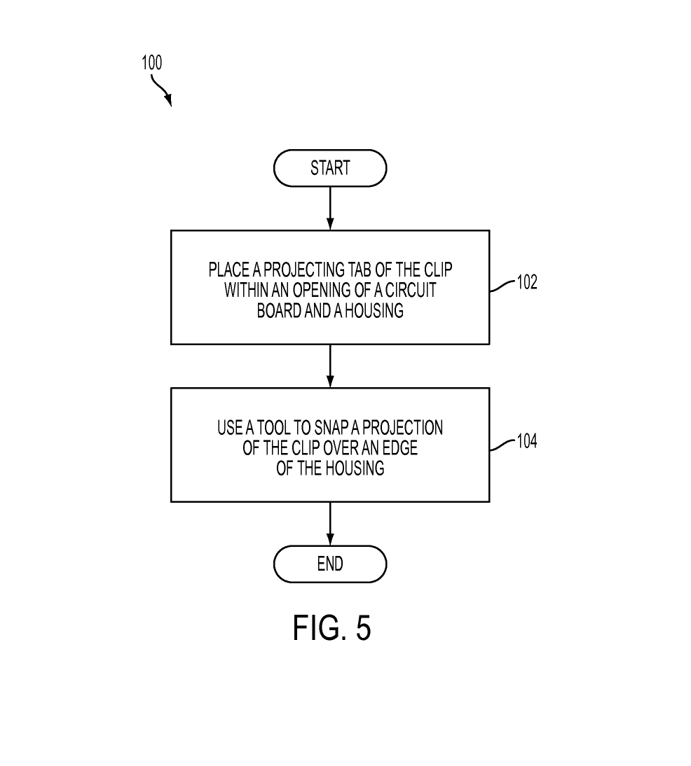

FIG. 5 is a process flow diagram illustrating an exemplary approach for securing the clip 30 to the circuit board 20. Referring generally to FIGS. 1-5, method 100 may begin at step 102, where an operator places the projecting tab 42 of the clip 30 within the opening 40 of the non-conductive substrate 24 and the opening 41 of the housing 26, and the flange 50 is seated against the ground plane 34 of the circuit board 20. Method 100 may then proceed to step 102.

In step 102, the tool 100 is used by an operator to slide the projection 60 of the clip 30 over an edge 110 of the housing 26. The projection 60 of the clip 30 then snaps or clips into position, thus securing the clip 30 to the housing. Method 100 may then terminate.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description.

Having thus described the invention, it is claimed:

1. A housing assembly, comprising:
a circuit board having a main body and a ground plane, the main body defining an opening therethrough in the circuit board;
a housing for receiving the circuit board; and
a clip for securing the circuit board to the housing, the clip including a projecting tab and a flange, the projecting tab received by the opening in the circuit board and the flange contacting the ground plane.

2. The housing assembly in claim 1, wherein the clip includes a projection configured to contact a portion of the housing, wherein the flange of the clip is configured to exert a first biasing force upon the ground plane of the circuit board, and the projection is configured to exert a second biasing force upon the housing.

3. The housing assembly in claim 2, wherein the first biasing force and the second biasing force generally oppose one another.

4. The housing assembly in claim 1, wherein the clip is constructed from spring steel.

5. The housing assembly in claim 1, wherein the housing is constructed from an electrically conductive material.

6. The housing assembly in claim 1, wherein the projecting tab is a portion of the flange that is generally perpendicular to a remaining portion the flange.

7. The housing assembly in claim 1, wherein the projecting tab is positioned along a midsection of the clip.

8. The housing assembly in claim 1, wherein the projecting tab is offset from a midsection of the clip.

9. The housing assembly in claim 1, wherein the housing assembly is part of an electric power steering (EPS) assembly.

10. An electric power steering (EPS) assembly, comprising:
a housing assembly comprising:
a circuit board having a main body and a ground plane, the main body defining an opening therethrough in the circuit board;
a housing for receiving the circuit board; and
a clip for securing the circuit board to the housing, the clip including a projecting tab, a flange, and a projection, the projecting tab received by the opening in the circuit board, the flange contacting the ground plane, and the projection contacting a portion of the housing.

11. The EPS assembly in claim 10, wherein the flange of the clip is configured to exert a first biasing force upon the ground plane of the circuit board, and the projection is configured to exert a second biasing force upon the housing.

12. The EPS assembly in claim 11, wherein the first biasing force and the second biasing force generally oppose one another.

13. The EPS assembly in claim 10, wherein the clip is constructed from spring steel.

14. The EPS assembly in claim 10, wherein the housing is constructed from an electrically conductive material.

15. The EPS assembly in claim 10, wherein the projecting tab is a portion of the flange that is generally perpendicular to a remaining portion the flange.

16. The EPS assembly in claim 10, wherein the projecting tab is positioned along a midsection of the clip.

17. The EPS assembly in claim 10, wherein the projecting tab is offset from a midsection of the clip.

18. A method of securing a circuit board to a housing by a clip, comprising:
placing a projecting tab of the clip within an opening of the circuit board;
seating a flange of the clip against a ground plane of the circuit board; and
sliding a projection of the clip over an edge of the housing to secure the clip to the circuit board and the housing.

19. The method in claim 18, comprising providing a tool that includes a securing portion that contacts the clip, wherein the tool is directed in a first direction that is generally orthogonal to the housing to urge the projection of the clip over the edge of the housing.

20. The method in claim 19, wherein the tool includes a profile that generally conforms to an outer profile of the clip.
